(19) United States
(12) Patent Application Publication
(10) Pub. No.: US 2017/0104526 A1
(43) Pub. Date: Apr. 13, 2017

(54) STRESSED OPTICAL TRANSMITTER AND METHOD OF COMPLIANCE TESTING AN OPTICAL RECEIVER

(71) Applicant: TYCO ELECTRONICS CORPORATION, Berwyn, PA (US)

(72) Inventor: Jonathan Lee, Harrisburg, PA (US)

(21) Appl. No.: 14/937,320

(22) Filed: Nov. 10, 2015

Related U.S. Application Data
(60) Provisional application No. 62/238,569, filed on Oct. 7, 2015.

(51) Int. Cl. H04B 10/079; H01S 5/06; H04B 10/61; H04B 10/58; H04B 10/516; H01S 5/062; H04B 10/2507

(52) U.S. Cl. CPC H04B 10/0795; H01S 5/062; H01S 5/0607; H04B 10/2507; H04B 10/58; H04B 10/516; H04B 10/616

(57) ABSTRACT

A stressed optical transmitter for compliance testing an optical receiver includes an electrical signal generator generating a test electrical signal and an optical distortion module including an EOC converting the test electrical signal to an optical signal. The optical signal distortion module selectively distorts the optical signal to generate a stressed optical test signal. The optical distortion module emits the stressed optical test signal for compliance testing the optical receiver. A method of compliance testing an optical receiver includes generating a test electrical signal using a test pattern generator, receiving the test electrical signal at an optical distortion module, converting the test electrical signal to an optical signal, selectively distorting the optical signal to generate a stressed optical test signal, emitting the stressed optical test signal, and receiving the stressed optical test signal at an optical receiver for compliance testing the optical receiver.

### CROSS REFERENCE TO RELATED APPLICATIONS

This application claims the benefit of U.S. Provisional Application No. 62/238,569 filed Oct. 7, 2015, the subject matter of which is herein incorporated by reference in its entirety.

### BACKGROUND

The subject matter herein relates generally to a stressed optical transmitter and method of testing an optical receiver.

IEEE standard 802.3bm-2015 sets forth a stressed receiver conformance test for conformance testing an optical receiver. This IEEE standard specifies that a reference optical transmitter be used for optical receiver compliance testing. The characteristics of the referenced transmitter are explicitly defined, and a methodology for its creation is provided in the standard. However, the methodology provided is resource intensive and it has proven difficult to produce the testing transmitter, due in part to there being a lack of a commercially available ideal electrical-to-optical (E-O) converter.

The stressed receiver conformance test set forth in the standard provides stress conditioning to the electrical signal generated by the test pattern signal generator and the stress conditioned electrical signal is transferred to the optical domain via an ideal E-O converter. The resulting stressed optical signal is used for conformance testing the optical receiver. However, an E-O converter, such as one consisting of a linear driver and an 850 nanometer (nm) optical source combination capable of supporting 28.7125 Gigabit per second (Gbps) data rates, is not readily available.

### SUMMARY

In an embodiment, a stressed optical transmitter for compliance testing an optical receiver includes an electrical signal generator generating a test electrical signal and an optical distortion module. The optical distortion module includes an E-O converter (EOC) that receives the test electrical signal, converts the test electrical signal to an optical signal, and has the ability to apply signal distortion. The optical distortion module selectively distorts the optical signal to generate a conforming stressed optical test signal that can be used for optical receiver compliance testing.

Optionally, the optical distortion module may selectively degrade the optical signal to generate the stressed optical test signal. The stressed optical test signal meets the targeted stressed eye closure and jitter characteristics of a conforming 100G-base SR4 reference optical transmitter. The stressed optical test signal may be degraded from an optimal optical signal with a majority of the degradation from the optimal optical signal to the stressed optical test signal being achieved via the optical distortion module.

Optionally, the optical module may selectively distort the optical signal via bandwidth limiting of the optical signal to generate the stressed optical test signal. The optical distortion module may selectively distort the optical signal by modal dispersion of the optical signal to generate the stressed optical test signal. The optical distortion module may selectively distort the optical signal via linear optical attenuation of the optical signal to generate the stressed optical test signal.

Optionally, the EOC may include a driver and a laser generator operably coupled to the driver. The driver may receive the test electrical signal and the driver may modulate current supplied to the laser generator to selectively distort the optical signal to generate the stressed optical test signal. The driver may supply a different current to the laser generator than required by the test electrical signal to distort the optical signal. The driver may vary the modulation current to the laser generator to distort the optical signal. The driver may adjust pre-emphasis settings to at least one of overshoot or undershoot the optical signal to distort the optical signal. Optionally, the optical distortion module may adjust the resistive load of the laser generator to distort the optical signal. The laser generator may be a vertical cavity surface emitting laser (VCSEL).

Optionally, the optical distortion module may include a variable optical attenuator (VOA) downstream of the EOC. The VOA may degrade the optical signal generated by the EOC to distort the optical signal to generate the stressed optical test signal. An optical fiber may be provided between the EOC and the VOA. A length of the optical fiber may be variably selected to control the amount of optical signal distortion of the optical signal.

Optionally, the electrical signal generator may include a signal pattern generator and an electrical signal distortion module that stress conditions the electrical test signal presented to the optical distortion module. The electrical signal distortion module may introduce noise to the electrical signal generated by the signal pattern generator. The electrical signal distortion module may cause signal distortion in the electrical domain and the optical distortion module may cause signal distortion in the optical domain. Optionally, a majority of the signal distortion of the stressed optical test signal is in the optical domain caused by the optical distortion module and a minority of the signal distortion of the stressed optical test signal is in the electrical domain caused by the electrical signal distortion module.

In another embodiment, a method of compliance testing an optical receiver is provided including generating an electrical signal, receiving the electrical signal at an optical signal generator having an optical distortion module, generating an optical signal at the optical signal generator based on the electrical signal, selectively distorting at least one of the electrical signal or the optical signal using the optical distortion module to generate a stressed optical test signal, emitting the stressed optical test signal, and receiving the stressed optical test signal at an optical receiver for compliance testing the optical receiver.

### BRIEF DESCRIPTION OF THE DRAWINGS

FIG. 1 is a schematic illustration of a stressed optical transmitter formed in accordance with an exemplary embodiment used for compliance testing of an optical receiver.

FIG. 2 is a schematic illustration of the stressed optical transmitter in accordance with an exemplary embodiment.

FIG. 3 is a schematic illustration of the stressed optical transmitter coupled to a calibration device.

FIG. 4 illustrates a method of compliance testing of an optical receiver in accordance with an exemplary embodiment.

### DETAILED DESCRIPTION

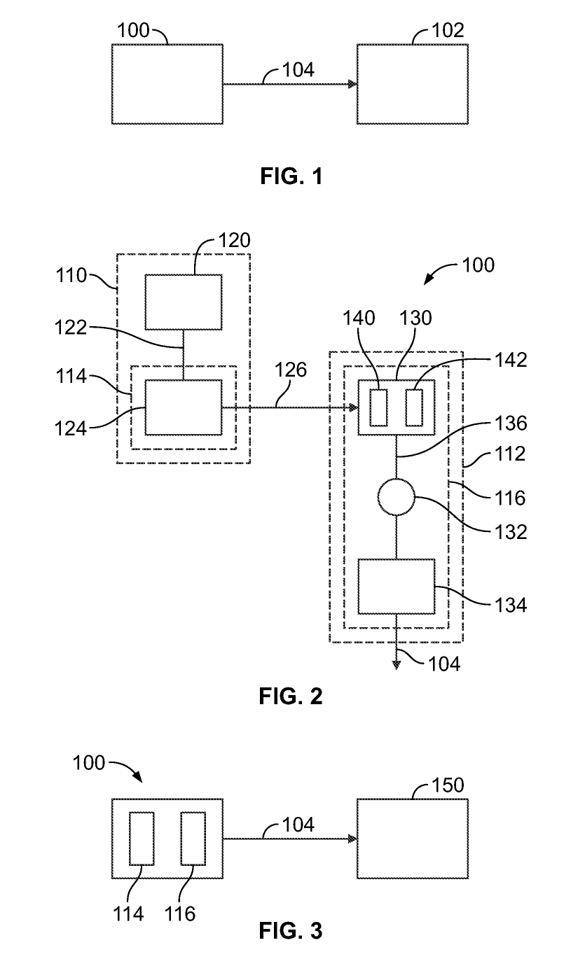

FIG. 1 is a schematic illustration of a stressed optical transmitter 100 formed in accordance with an exemplary embodiment used for compliance testing of an optical receiver 102. The stressed optical transmitter 100 transmits a conditioned or stressed optical test signal 104 over an optical fiber to the optical receiver 102 during compliance testing. The stressed optical test signal 104 is conditioned by selectively distorting the optical signal for compliance testing. In an exemplary embodiment, the optical signal degradation is achieved in the optical domain, such as via bandwidth limiting, modal dispersion, linear optical attenuation or other optical signal degradation. Optionally, at least a portion of the signal degradation is achieved via electrical signal degradation prior to converting the electrical signal to an optical signal, such as using an electrical-to-optical converter (EOC). The EOC uses the partially degraded signal to generate an optical signal and then the stressed optical transmitter 100 further degrades such optical signal to achieve the stressed optical test signal 104.

The stressed optical test signal 104 meets the targeted stressed eye closure and jitter characteristics of a conforming 100G-base SR4 reference optical transmitter (as set forth in IEEE standard 802.3bm-2015, for example). The stressed optical transmitter 100 may be used to simulate the optical signal at the receiver assuming a worst-case optical channel. The stressed optical test signal 104 may be degraded from an optimal optical signal with a majority of the degradation from the optimal optical signal to the stressed optical test signal 104 being achieved by optical signal distortion rather than electrical signal distortion.

FIG. 2 is a schematic illustration of the stressed optical transmitter 100 in accordance with an exemplary embodiment. The stressed optical transmitter 100 includes an electrical signal generator 110 and an optical signal generator 112. The electrical signal generator 110 generates an electrical signal that is transmitted to the optical signal generator 112. The optical signal generator 112 uses the electrical signal to generate the stressed optical test signal 104, which is used for compliance testing of the optical receiver 102 (shown in FIG. 1). The optical signal generator 112 selectively distorts the optical signal to generate the stressed optical test signal 104. The optical signal generator 112 emits the stressed optical test signal 104 for compliance testing the optical receiver 102.

In an exemplary embodiment, the electrical signal generator 110 includes an electrical signal distortion module 114 used to partially distort the electrical signal to create a stressed or conditioned electrical signal. The stressed optical test signal 104 is conditioned or stressed by the electrical signal distortion module 114 in the electrical domain. The optical signal generator 112 includes an optical distortion module 116 used to partially distort the optical signal to create the stressed optical test signal 104. The stressed optical test signal 104 is conditioned or stressed by the optical distortion module 116 in the optical domain. A majority of the signal distortion may occur in the optical domain by the optical distortion module 116. The electrical signal distortion module 114 and/or the optical distortion module 116 may each alter or change one or more stress conditioning characteristics to distort the stressed optical test signal 104.

The electrical signal generator 110 includes a signal pattern generator 120 that generates electrical signals 122. The electrical signal generator 110 includes at least one stress conditioning component 124 as part of the electrical signal distortion module 114. The stress conditioning component 124 distorts the electrical signal 122. The stress conditioning component 124 alters or changes one or more stress conditioning characteristics to distort the stressed optical test signal 104. For example, the stress conditioning component 124 degrades the electrical signal 122. The stress conditioning component 124 may be a filter, and amplitude interferer, a noise generator, a limiter, or another type of stress conditioning component. The stress conditioning component 124 may selectively vary trace lengths, trace widths, trace mismatch, and the like, to introduce noise to the electrical signal 122. The stress conditioning component 124 negatively affects the electrical signal 122. The stress conditioning component 124 outputs a test electrical signal 126, which is output to the optical signal generator 112. The test electrical signal 126 is degraded or distorted with respect to the electrical signal 122 generated by the signal pattern generator 120.

In an alternative embodiment, rather than stress conditioning the electrical signal 122, all of the signal distortion may be achieved by the optical signal generator 112 and the corresponding optical distortion module 116. In such embodiments, the electrical signal generator 110 does not include an electrical signal distortion module 114 or any stress conditioning components 124. Rather, the electrical signal 122 generated by the signal pattern generator 120 is transmitted to the optical signal generator 112 without distorting the electrical signal 122.

In an exemplary embodiment, the optical signal generator 112 includes an optical engine or electrical to optical converter (EOC) 130, a length of optical fiber 132 and a variable optical attenuator (VOA) 134. The optical signal generator 112 may include other components in alternative embodiments. The optical signal generator 112 may include fewer components in other various embodiments. For example, the optical signal generator 112 may be provided without the length of optical fiber 132 and/or without the VOA 134.

In an exemplary embodiment, the EOC 130, the length of optical fiber 132 and the VOA 134 form components of the optical distortion module 116. The EOC 130, the length of optical fiber 132 and the VOA 134 all provide signal conditioning or stressing to distort the optical signal to achieve the desired stressed optical test signal 104. The EOC 130, the length of optical fiber 132 and the VOA 134 may alter or change one or more stress conditioning characteristics to distort the stressed optical test signal 104. The optical distortion module 116 may selectively distort the optical signal by bandwidth limiting of the optical signal to generate the stressed optical test signal 104. The optical distortion module 116 may selectively distort the optical signal by modal dispersion of the optical signal to generate the stressed optical test signal 104. The optical distortion module 116 may selectively distort the optical signal by a linear optical attenuation of the optical signal to generate the stressed optical test signal 104.

The length of optical fiber 132 provides signal conditioning by distorting the optical signal along the length of the optical fiber 132. The length of the optical fiber 132 affects the distortion. For example, a longer length may provide more distortion, while a shorter length may provide less distortion. The optical fiber 132 may be optical multi-mode 4 (OM4) optical fiber, or another type of optical fiber. Optionally, the optical fiber 132 may be approximately 100 meters (m) in length. Longer or shorter lengths may be provided in alternative embodiments.

The VOA 134 provides signal conditioning by distorting the optical signal. The VOA 134 may be a linear optical attenuator. The VOA 132 may degrade the optical signal by reducing the power level of the optical signal. Such distortion affects the stressed optical test signal 104 emitted from the stressed optical transmitter 100.

The EOC 130 receives the test electrical signal 126 and converts the test electrical signal 126 to an optical signal 136. The optical signal 136 is transmitted through the optical fiber 132 to the VOA 134. In an exemplary embodiment, the EOC 130 includes a driver 140 and a laser generator 142 operably coupled to the driver 140. The driver 140 may be a processor or chip. The driver 140 may include one or more circuits that may modulate current supplied to the laser generator for operation of the laser generator 142. The laser generator 142 may be a vertical cavity surface emitting laser (VCSEL).

The driver 140 receives the test electrical signal 126 from the electrical signal generator 110. The driver 140 modulates the current supplied to the laser generator 142. In an exemplary embodiment, the driver 140 selectively distorts the signal by affecting how the current is modulated, which affects the stressed optical test signal 104. For example, the driver 140 may vary the current to the laser generator to distort the optical signal 136, such as by purposely distorting the output by supplying a different current to the laser generator than required by the test electrical signal 126 to distort the optical signal 136 (e.g., a different signal than a linear driver would supply). The driver 140 may vary the modulation current to the laser generator 142 to distort the optical signal 136. The driver 140 may adjust pre-emphasis settings to at least one of overshoot or undershoot the optical signal 136, causing distortion. Other aspects of the driver 140 operation may be selectively adjusted or controlled to distort the current used to drive the laser generator 142, thus causing stress conditioning and distortion in the stressed optical test signal 104. The driver 140 of the EOC 130 may thus cause distortion in the electrical domain, which causes distortion to the stressed optical test signal 104. Such electrical distortion is independent of the electrical signal generator 110 and is applied to the test electrical signal 126 after entering the optical signal generator 112.

The laser generator 142 is driven by the driver 140. For example, the current supplied to the laser generator 142 is used to generate the optical signal 136. The optical signal generated by the laser generator 142 may be degraded or distorted by the laser generator 142 to affect the stressed optical test signal 104. For example, the laser generator 142 may adjust a resistive load thereof to distort the optical signal 136. The laser generator 142 may filter the current received or the laser generated to degrade the optical signal 136.

Other components may be provided to distort the stressed optical test signal 104. The stressed optical test signal 104 is affected by the electrical signal received and acted upon by the driver 140. The stressed optical test signal 104 is affected by the optical signal 136 generated by the laser generator 142 and any downstream components acting on the optical signal 136. The electrical signal distortion module 114 may cause signal distortion in the electrical domain and the optical distortion module 116 may cause signal distortion in the electrical domain and/or the optical domain. Optionally, a majority of the signal distortion of the stressed optical test signal 104 is in the optical domain caused by the optical distortion module 116 and a minority of the signal distortion of the stressed optical test signal 104 is in the electrical domain caused by the electrical signal distortion module 114.

FIG. 3 is a schematic illustration of the stressed optical transmitter 100 coupled to a calibration device 150. The stressed optical test signal 104 is transmitted from the stressed optical transmitter 100 to the calibration device 150. The calibration device 150 monitors the stressed optical test signal 104 to confirm that the stressed optical test signal 104 falls within the parameters needed for compliance testing of the optical receiver 102 (shown in FIG. 1). For example, the calibration device 150 may monitor the stressed optical test signals 104 to confirm that the stressed optical test signal 104 falls within the parameters set forth in IEEE standard 802.3bm-2015 relating to the 100G-base SR4 standard. The calibration device 150 may include a reference receiver, an oscilloscope and/or other components. The calibration device 150 may include a controller or other processing device that analyzes the stressed optical test signal 104. The calibration device 150 may include an EOC for converting the optical signal to an electrical signal. The calibration device may be connected to a host system, such as a computer for analysis or processing. The calibration device, or host system, may include a display, a user interface, a keyboard, a mouse or other components for interacting with the host system.

During calibration of the stressed optical transmitter 100, the stressed optical test signals 104 may be transmitted to the calibration device 150 and analyzed by the calibration device 150 to measure parameters such as signaling rate, center wavelength, spectral width, optical modulation amplitude, transmitter and dispersion eye closure, extinction ratio, optical return loss tolerance, encircled flux, damage threshold, average receive power, receiver reflectance, stressed receiver sensitivity, stressed eye closure, stressed eye 32 jitter, stressed eye J4 jitter, stressed receiver eye mask definition hit ratio, average optical power, and the like. As different stress conditioning characteristics of the electrical signal distortion module 114 and/or the optical distortion module 116 are changed, the effects of the distortion of the stressed optical test signal 104 may be measured by the calibration device 150 to achieve an operational stressed optical transmitter 100 that satisfies the requirements or standards.

As used herein, the terms “system,” “unit,” or “module” may include a hardware and/or software system that operates to perform one or more functions. For example, a module, unit, or system may include a computer processor, controller, chip, or other logic-based device that performs operations based on instructions stored on a tangible and non-transitory computer readable storage medium, such as a computer memory. Alternatively, a module, unit, or system may include a hard-wired device that performs operations based on hard-wired logic of the device. Various modules or units shown in the attached figures may represent the hardware that operates based on software or hardwired instructions, the software that directs hardware to perform the operations, or a combination thereof.

“Systems,” “units,” or “modules” may include or represent hardware and associated instructions (e.g., software stored on a tangible and non-transitory computer readable storage medium, such as a computer hard drive, ROM, RAM, or the like) that perform one or more operations described herein. The hardware may include electronic circuits that include and/or are connected to one or more logic-based devices, such as microprocessors, processors, controllers, or the like. These devices may be off-the-shelf devices that are appropriately programmed or instructed to perform operations described herein from the instructions described above. Additionally or alternatively, one or more of these devices may be hard-wired with logic circuits to perform these operations.

It should be noted that the particular arrangement of components (e.g., the number, types, placement, or the like) of the illustrated embodiments may be modified in various alternate embodiments. In various embodiments, different numbers of a given module or unit may be employed, a different type or types of a given module or unit may be employed, a number of modules or units (or aspects thereof) may be combined, a given module or unit may be divided into plural modules (or sub-modules) or units (or sub-units), a given module or unit may be added, or a given module or unit may be omitted.

It should be noted that the various embodiments may be implemented in hardware, software or a combination thereof. The various embodiments and/or components, for example, the units, modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid state drive, optical drive, and the like. The storage device may also be other similar means for loading computer programs or other instructions into the computer or processor.

As used herein, the term “computer” and “controller” may each include any processor-based or microprocessor-based system including systems using microcontrollers, reduced instruction set computers (RISC), application specific integrated circuits (ASICs), logic circuits, GPUs, FPGAs, and any other circuit or processor capable of executing the functions described herein. The above examples are exemplary only, and are thus not intended to limit in any way the definition and/or meaning of the term “controller” or “computer.”

The computer, module, or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer, module, or processor as a processing machine to perform specific operations such as the methods and processes of the various embodiments described and/or illustrated herein. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program. The individual components of the various embodiments may be virtualized and hosted by a cloud type computational environment, for example to allow for dynamic allocation of computational power, without requiring the user concerning the location, configuration, and/or specific hardware of the computer system.

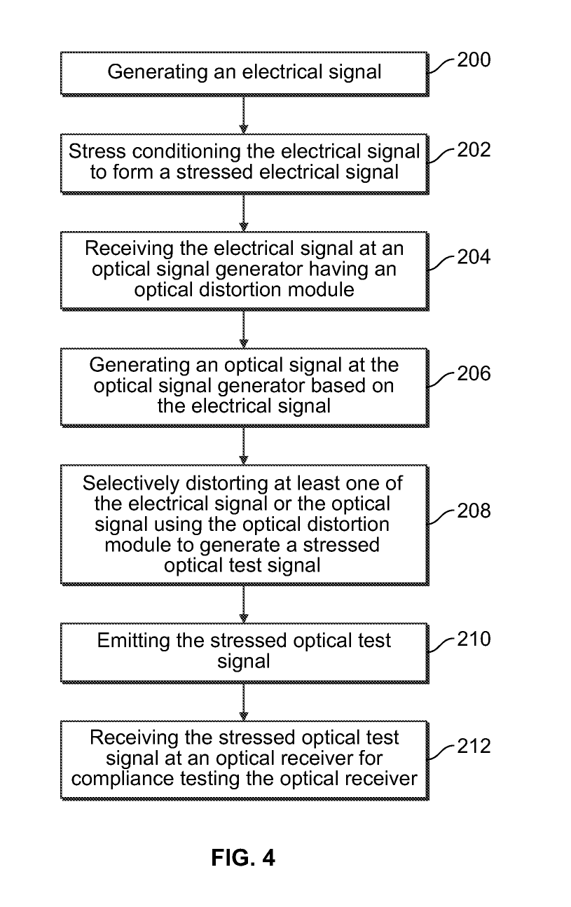

FIG. 4 illustrates a method of compliance testing an optical receiver in accordance with an exemplary embodiment. The method of compliance testing an optical receiver includes the step of generating an electrical signal, at 200. Optionally, the electrical signal may be generated by a signal pattern generator. Optionally, the method may include the step of stress conditioning the electrical signal to form a stressed electrical signal, at 202. The stressed electrical signal may be degraded or distorted with respect to the electrical signal generated by the signal pattern generator.

The method includes the step of receiving the electrical signal (or stressed electrical signal) at an optical signal generator having an optical distortion module, at 204. The electrical signal may be received at an optical engine, such as an EOC. The electrical signal may be received by a driver of the EOC.

The method includes the step of generating an optical signal at the optical signal generator based on the electrical signal (or stressed electrical signal), at 206. The optical signal may be generated by a laser generator of the EOC. Optionally, the laser generator may be a VCSEL device.

The method includes the step of selectively distorting at least one of the electrical signal or the optical signal using the optical distortion module to generate a stressed optical test signal, at 208. The optical distortion module distorts the signal downstream of the electrical signal generator. For example, the optical distortion module receives the electrical signal (or the stressed electrical signal) and provides degradation and distortion of such electrical signal. For example, the optical distortion module is part of the optical signal generator, which includes the EOC. The EOC may form part of the optical distortion module as the EOC may provide stress conditioning.

The EOC may provide stress conditioning in the electrical domain or in the optical domain. For example, the EOC may selectively distort the signal by providing stress conditioning at the driver. The EOC may selectively distort the signal by providing stress conditioning at the laser generator. The EOC may selectively distort the signal by bandwidth limiting of the signal to generate the stressed optical test signal. The EOC may selectively distort the signal by modal dispersion of the signal to generate the stressed optical test signal. The EOC may selectively distort the signal by varying the modulation current supplied from a driver to a laser generator to selectively distort the optical signal to generate the stressed optical test signal. The EOC may selectively distort the signal by varying the bias current supplied from a driver to a laser generator to generate the stressed optical test signal. The EOC may selectively distort the signal by varying the modulation current supplied from a driver to a laser generator to generate the stressed optical test signal. The EOC may selectively distort the signal by adjusting pre-emphasis settings from a driver to a laser generator to at least one of overshoot or undershoot the optical signal to distort the optical signal. The EOC may selectively distort the signal by adjusting a resistive load of a laser generator to distort the optical signal. The EOC may selectively distort the signal by providing filtering of the electrical signal or the optical signal.

Other components may provide signal distortion. For example, the optical distortion module may include a VOA. The VOA may provide signal distortion of the optical signal by providing linear optical attenuation of the optical signal to generate the stressed optical test signal. Selective distortion may be provided by variably selecting a length of optical fiber to transmit the optical signal and degrade the optical signal to generate the stressed optical test signal. Other components may provide signal distortion of the optical signal and/or the electrical signal as well.

The method includes the step of emitting the stressed optical test signal, at 210. The method includes the step of receiving the stressed optical test signal at an optical receiver for compliance testing the optical receiver, at 212.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled.

As used in the description, the phrase “in an exemplary embodiment” and the like means that the described embodiment is just one example. The phrase is not intended to limit the inventive subject matter to that embodiment. Other embodiments of the inventive subject matter may not include the recited feature or structure. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

What is claimed is:

1. A stressed optical transmitter for compliance testing an optical receiver, the stressed optical transmitter comprising:
an electrical signal generator generating a test electrical signal;
an optical distortion module having an electrical to optical converter (EOC) receiving the test electrical signal and converting the test electrical signal to an optical signal, the optical signal distortion module selectively distorting the optical signal to generate a stressed optical test signal, the optical distortion module emitting the stressed optical test signal for compliance testing the optical receiver.

2. The stressed optical transmitter of claim 1, wherein the optical distortion module significantly degrades the optical signal to generate the stressed optical test signal.

3. The stressed optical transmitter of claim 1, wherein the stressed optical test signal meets the targeted stressed eye closure and jitter characteristics conforming to a 100G-base SR4 standard.

4. The stressed optical transmitter of claim 1, wherein the stressed optical test signal is degraded from an optimal optical signal, a majority of the degradation from the optimal optical signal to the stressed optical test signal is achieved by the optical distortion module.

5. The stressed optical transmitter of claim 1, wherein the optical distortion module selectively distorts the optical signal by bandwidth limiting of the optical signal to generate the stressed optical test signal.

6. The stressed optical transmitter of claim 1, wherein the optical distortion module selectively distorts the optical signal by modal dispersion of the optical signal to generate the stressed optical test signal.

7. The stressed optical transmitter of claim 1, wherein the optical distortion module selectively distorts the optical signal by a linear optical attenuation of the optical signal to generate the stressed optical test signal.

8. The stressed optical transmitter of claim 1, wherein the EOC includes a driver and a laser generator operably coupled to the driver, the driver receiving the test electrical signal, the driver modulating current supplied to the laser generator to selectively distort the optical signal to generate the stressed optical test signal.

9. The stressed optical transmitter of claim 8, wherein the driver selectively supplies a different current to the laser generator than required by the test electrical signal to distort the optical signal.

10. The stressed optical transmitter of claim 8, wherein the driver selectively varies the modulation current to the laser generator to distort the optical signal.

11. The stressed optical transmitter of claim 8, wherein the driver adjusts pre-emphasis settings to at least one of overshoot or undershoot the optical signal to distort the optical signal.

12. The stressed optical transmitter of claim 8, wherein the optical distortion module adjusts a resistive load of the laser generator to distort the optical signal.

13. The stressed optical transmitter of claim 8, wherein the laser generator is a vertical cavity surface emitting laser (VCSEL).

14. The stressed optical transmitter of claim 1, wherein the optical distortion module includes a variable optical attenuator (VOA) downstream of the EOC, the VOA degrading the optical signal generated by the EOC to distort the optical signal to generate the stressed optical test signal.

15. The stressed optical transmitter of claim 14, further comprising an optical fiber between the EOC and the VOA, a length of the optical fiber being variably selected to control an amount of optical signal distortion of the optical signal.

16. The stressed optical transmitter of claim 1, wherein the electrical signal generator includes a signal pattern generator and an electrical signal distortion module that stress conditions an electrical signal generated by the signal pattern generator to degrade the electrical signal generated by the signal pattern generator and defined the test electrical signal.

17. The stressed optical transmitter of claim 16, wherein the electrical signal distortion module introduces noise to the electrical signal generated by the signal pattern generator to define the test electrical signal.

18. The stressed optical transmitter of claim 16, wherein the electrical signal distortion module causes signal distortion in the electrical domain and the optical distortion module causes signal distortion in the optical domain.

19. The stressed optical transmitter of claim 18, wherein a majority of the signal distortion of the stressed optical test signal is in the optical domain caused by the optical distortion module and a minority of the signal distortion of the stressed optical test signal is in the electrical domain caused by the electrical signal distortion module.

20. A method of compliance testing an optical receiver comprising:
generating an electrical signal;
receiving the electrical signal at an optical signal generator having an optical distortion module;
generating an optical signal at the optical signal generator based on the electrical signal;
selectively distorting at least one of the electrical signal or the optical signal using the optical distortion module to generate a stressed optical test signal;
emitting the stressed optical test signal; and
receiving the stressed optical test signal at an optical receiver for compliance testing the optical receiver.

21. The method of claim 20, wherein said selectively distorting comprises bandwidth limiting of the optical signal to generate the stressed optical test signal.

22. The method of claim 20, wherein said selectively distorting comprises modal dispersion of the optical signal to generate the stressed optical test signal.

23. The method of claim 20, wherein said selectively distorting comprises linear optical attenuation of the optical signal to generate the stressed optical test signal.

24. The method of claim 20, wherein said selectively distorting comprises modulating current supplied from a driver to a laser generator to selectively distort the optical signal to generate the stressed optical test signal.

25. The method of claim 20, wherein said selectively distorting comprises modulating current supplied from a driver to a laser generator by supplying a different current to the laser generator than required by the electrical signal to selectively distort the optical signal to generate the stressed optical test signal.

26. The method of claim 20, wherein said selectively distorting comprises modulating current supplied from a driver to a laser generator by selectively modulating the current to distort the optical signal to generate the stressed optical test signal.

27. The method of claim 20, wherein said selectively distorting comprises adjusting pre-emphasis settings from a driver to a laser generator to at least one of overshoot or undershoot the optical signal to distort the optical signal.

28. The method of claim 20, wherein said selectively distorting comprises adjusting a resistive load of a laser generator to distort the optical signal.

29. The method of claim 20, wherein said selectively distorting comprises variably selecting a length of optical fiber to transmit the optical signal and degrade the optical signal to generate the stressed optical test signal.

30. The method of claim 20, further comprising selectively distorting the electrical signal using an electrical signal distortion module to generate a stressed electrical signal transmitted to the optical signal generator.
